(19) United States
(12) Patent Application Publication
(10) Pub. No.: US 2024/0194443 A1
(43) Pub. Date: Jun. 13, 2024

(54) ION MILLING DEVICE

(71) Applicant: Hitachi High-Tech Corporation, Tokyo (JP)

(72) Inventors: Kengo ASAI, Tokyo (JP); Hisayuki TAKASU, Tokyo (JP); Shota AIDA, Tokyo (JP)

(21) Appl. No.: 18/286,826

(22) PCT Filed: May 19, 2021
(86) PCT No.: PCT/JP2021/019012

§ 371 Date: Oct. 13, 2023

(51) Int. Cl. H01J 37/305; H01J 37/08; H01J 37/26

(52) U.S. Cl. CPC H01J 37/3053; H01J 37/08; H01J 37/265

(57) ABSTRACT

Provided is an ion milling device that can dramatically improve processing speed controllability and processing profile reproducibility. The ion milling device includes: an ion gun attached to a vacuum chamber and configured to emit an unfocused ion beam; a sample stand disposed in the vacuum chamber and configured to hold a sample; an ion beam characteristic measurement mechanism configured to measure an ion beam characteristic for estimating a processing profile of the sample processed by the ion beam; and a control unit. A magnetic field generation device is configured to generate a magnetic field in an ionization chamber of the ion gun and includes an electromagnet including an electromagnetic coil and a magnetic path. The control unit controls a value of a current, which is applied to the electromagnetic coil, based on the ion beam characteristic measured by the ion beam characteristic measurement mechanism.

### TECHNICAL FIELD

The present invention relates to an ion milling device suitable for pretreatment processing of a sample to be observed with an electron microscope.

### BACKGROUND ART

An ion milling method is a processing method in which accelerated ions are made to collide with a sample, and the sample is cut utilizing a sputtering phenomenon in which the ions flick atoms and molecules. The method is used with metals, glasses, ceramics, electronic components, composite materials, and the like as targets, and is widely utilized for the composite materials as a cross-sectional sample preparation method for acquiring a morphological image, a sample composition image, and a channeling image by a scanning electron microscope, or acquiring an X-ray analysis, a crystal orientation analysis, and the like, for example, for the purpose of analyzing an internal structure, a cross-sectional area shape, a film thickness evaluation, a crystal state, failure, and a cross section of a foreign substance. Further, in recent years, with an increase in a processing speed of the ion milling device, an application range is expanded to include structural observation and the like for the purpose of process management of a mass production process in a semiconductor field and the like.

In the ion milling device as described above, a small-sized penning discharge ion gun with a simple configuration is used as the ion gun. In the penning discharge ion gun, electrons emitted from a cathode perform a swirling motion because of a magnetic field of a permanent magnet and collide with a process gas introduced into the ion gun, thus being ionized. A first cathode and a second cathode having the same potentials are disposed at both ends of the anode, and the electrons that perform the swirling motion because of the magnetic field perform reciprocating motion between the cathodes, whereby an electron trajectory becomes longer and ionization efficiency is improved. Accordingly, there is an advantage that a high plasma density can be obtained.

A part of cations generated in an ionization chamber passes through a cathode outlet hole, is accelerated by an acceleration electrode, and is emitted from an acceleration electrode outlet hole to the outside. In order to increase a milling speed, it is necessary to increase an amount of the ions emitted from the ion gun. A high plasma density is essential for this purpose, and it is important to supply an appropriate magnetic field strength on an axis of the ion gun. A variation in the magnetic field strength causes a decrease in the plasma density, influences ion beam performance, and causes a processing shape of a sample processing surface to also vary. As described above, in order to implement high processing speed control and high processing profile reproducibility, it is important to stably supply an appropriate magnetic field strength to the ion gun.

The ion milling device irradiates a sample surface with an ion beam emitted from the penning discharge ion gun without focusing the ion beam, and performs the sample processing. An ion density distribution of the unfocused ion beam has characteristics that the ion density distribution is the highest at an irradiation center and decreases toward outside. Since the ion density is closely related to a processing speed of the sample, the ion density distribution is directly reflected in the processing shape of the sample processing surface. Therefore, when the ion milling device is used for pretreatment processing of the sample to be observed with an electron microscope, a difference in the ion density distribution is directly linked to a difference in an observation surface to be observed with the electron microscope.

PTL 1 discloses a basic structure of the penning discharge ion gun. A configuration of a penning ion gun is disclosed which includes a gas supply mechanism that supplies a gas into an ion gun, an anode that is disposed in the ion gun and to which a positive voltage is applied, a cathode that generates a potential difference between the cathode and the anode, and a permanent magnet. PTL 2 discloses a penning discharge ion gun that obtains a processing speed higher than that in the related art by limiting a magnetic field strength of a built-in magnet to an appropriate value.

### CITATION LIST

### Patent Literature

PTL 1: JPS53-114661A
PTL 2: JP2016-031870A

### SUMMARY OF INVENTION

### Technical Problem

With progress of the ion milling device in recent years, an application market has been widely expanded. Particularly, as the processing speed of the ion milling device is increased, the application range is also expanded to a field not originally assumed, and a case where sufficient results are not obtained in a related-art apparatus configuration and apparatus performance also appears. Specifically, in a related-art ion milling device, in order to quickly observe a structure, importance has been placed on how to implement high-speed processing, but in recent years, in addition to the high-speed processing, high processing accuracy has been required. For example, in order to manage a mass production line, there is a need to inspect, with the electron microscope, an evaluation sample pretreated by the ion milling device. In this case, in order to make evaluation conditions uniform, a plurality of ion milling devices placed in the mass production process are required to perform processing of the same shape on many samples always with high accuracy regardless of which ion milling device performs the processing and when the processing is performed. Particularly, it has been found that when a pattern appearing on a processing surface formed by the ion milling device is observed as mass production management of a semi-conductor integrated circuit device, processing speed controllability and processing profile reproducibility that can be achieved by the related-art ion milling device are insufficient. When an angle of a processing surface varies or a processing depth varies, a shape of a pattern appearing on the processing surface may also change. Therefore, since evaluation cannot be performed under the same conditions, and a correct evaluation result cannot be obtained, there is a problem that the method cannot be applied to process management that requires high processing accuracy.

### Solution to Problem

An ion milling device according to an embodiment of the invention includes: a vacuum chamber whose internal pressure is controlled by a vacuum exhaust system; an ion gun attached to the vacuum chamber and configured to emit an unfocused ion beam; a sample stand disposed in the vacuum chamber and configured to hold a sample; an ion beam characteristic measurement mechanism configured to measure an ion beam characteristic for estimating a processing profile of the sample processed by the ion beam; and a control unit, a magnetic field generation device configured to generate a magnetic field in an ionization chamber of the ion gun is an electromagnet including an electromagnetic coil and a magnetic path, and the control unit controls a value of a current, which is applied to the electromagnetic coil, based on the ion beam characteristic measured by the ion beam characteristic measurement mechanism.

### Advantageous Effects of Invention

An ion milling device that can dramatically improve processing speed controllability and processing profile reproducibility is provided. Other problems and novel features will become apparent from description in the present specification and accompanying drawings.

### BRIEF DESCRIPTION OF DRAWINGS

FIG. 1 is a configuration example of an ion milling device.

FIG. 2 is a cross-sectional view showing configurations of peripheral portions related to an ion gun.

FIG. 3A is a schematic view (cross-sectional view) of an ion beam and a sample processed by the ion beam.

FIG. 3B is a schematic view (top view) of the sample processed by the ion beam.

FIG. 4 is a diagram showing a relationship between an axial magnetic flux density of the ion gun and a milling speed.

FIG. 5 is a diagram schematically showing a state where a processing depth and a processing shape vary due to an influence of the axial magnetic flux density.

FIG. 6A is a diagram showing an example of a profile of the axial magnetic flux density.

FIG. 6B is a diagram showing an example of the profile of the axial magnetic flux density.

FIG. 7 shows an ion beam profile measured by an ion beam characteristic measurement mechanism.

FIG. 8 is a flowchart for adjusting ion beam irradiation conditions.

FIG. 9 shows another configuration example of the ion milling device.

FIG. 10 shows another configuration example of the ion milling device.

### DESCRIPTION OF EMBODIMENTS

Hereinafter, a preferred embodiment of the present invention will be described with reference to the drawings.

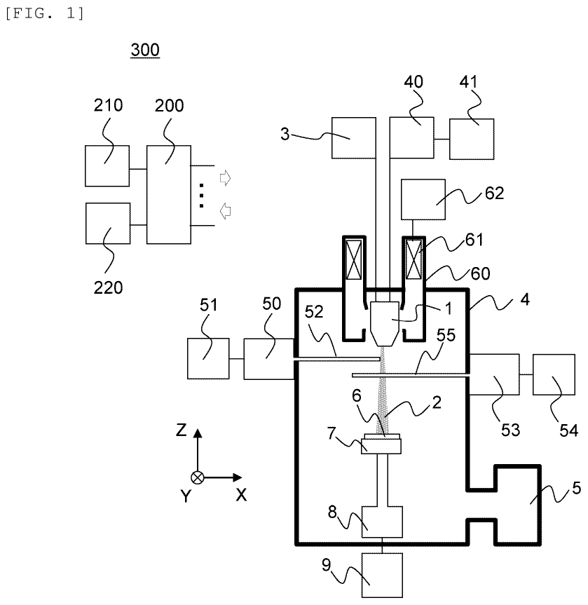

FIG. 1 is a schematic view showing a main part of an ion milling device 300 according to the present embodiment. A penning discharge ion gun 1 includes an element necessary for generating ions therein, and irradiates a sample 6 with an ion beam 2. An internal structure thereof will be described later. A gas source 41 is connected to the ion gun 1 via a gas supply mechanism 40, and a gas flow rate controlled by the gas supply mechanism 40 is supplied into a plasma generation chamber of the ion gun 1. The gas supply mechanism 40 includes all components for adjusting a flow rate of a gas to be ionized and supplying the gas to be ionized into the ion gun. For example, Ar gas is used as an introduced gas. Irradiation conditions of the ion beam 2 are controlled by an ion gun control unit 3. The ion gun control unit 3 includes all components for adjusting voltage conditions to be applied to components of the ion gun 1 and emitting the ion beam 2. A vacuum chamber 4 is controlled to an atmospheric pressure or vacuum by a vacuum exhaust system 5. The sample 6 is held on a sample stand 7, and the sample stand 7 is held by a sample stage 8. A sample stage drive unit 9 is provided to drive the sample stage 8.

In the ion milling device 300, since the ion beam 2 emitted from the ion gun 1 is emitted to the sample 6 without being focused, an ion beam distribution near an ion beam irradiation point of the sample 6 has characteristics that an ion density at a central portion is the highest and an ion density decreases from a center toward an outer side. Since the ion density is directly linked to a processing speed of the sample, a processing shape of the sample greatly depends on the ion beam distribution near the ion beam irradiation point. Therefore, the ion milling device 300 includes a mechanism (ion beam characteristic measurement mechanism) that measures an intensity distribution of the unfocused ion beam from the ion gun 1 for the purpose of improving processing speed controllability and processing profile reproducibility. A current probe 52 is disposed between the ion gun 1 and the sample 6, and a value of an ion beam current of the ion beam 2 is measured by an ammeter 50. The ammeter 50 includes all components for outputting, as the value of the current, ion information acquired by the current probe 52 irradiated with the ion beam 2. The current probe 52 is a linear conductive member that extends in a Y direction, and is reciprocally driven in an X direction orthogonal to the Y direction in the drawing by a current probe drive unit 51. In this way, the current probe 52 passes to cross the ion beam 2 while being moved in the X direction, and a value of a current that flows through the current probe 52 is measured for each position in the X direction, whereby it is possible to acquire an intensity distribution (hereinafter, referred to as an ion beam profile) of the ion beam current along a trajectory of the current probe 52.

The ion milling device 300 is controlled by an apparatus control unit 200. A display unit 210 and an input unit 220 for inputting an instruction of a user are connected to the apparatus control unit 200. Although illustration is omitted in the drawing, the apparatus control unit 200 is connected to control mechanisms for units of the ion milling device such as the ion gun control unit 3, the vacuum exhaust system 5, the gas supply mechanism 40, a coil control unit 62, and the sample stage drive unit 9. Further, the apparatus control unit 200 is connected to a monitor mechanism that monitors an operation situation of the ion milling device such as the ammeter 50.

The ion beam profile obtained from an output of the ammeter 50, control parameters and an operation state of the apparatus, and the like are displayed on the display unit 210. In a stage before an actual element is milled, the user can confirm the ion beam profile of the ion beam 2, and can adjust control parameters of the ion gun 1 via the input unit 220 such that desired ion beam characteristics are obtained. Further, an operation program for adjusting the control parameters may be executed based on a monitoring result obtained by the monitor mechanism of the ion milling device 300 including an ion beam characteristic measurement mechanism.

However, main control parameters for adjusting the ion beam characteristics are a discharge voltage and the gas flow rate in a related-art ion gun, and it is apparent from the study of inventors that adjustment based on the control parameters alone is insufficient. As a parameter having a large influence on the ion beam intensity, there is an axial magnetic flux density. A permanent magnet is used to generate a magnetic field in a related-art penning discharge ion gun. Due to nature of the permanent magnet, the magnetic field intensity cannot be controlled, and individual differences are large. It is difficult to cancel a variation in the axial magnetic flux density due to the individual difference of the permanent magnet by adjusting the discharge voltage and the gas flow rate. Therefore, a related-art ion milling device has a large machine difference, and has inevitably been insufficient in the processing speed controllability and the processing profile reproducibility.

In the ion milling device according to the present embodiment, in order to satisfy the high processing speed controllability and the high processing profile reproducibility required for mass production management, an axial magnetic field density of the ion gun 1 can be controlled. Therefore, a magnetic field generation device of the ion gun 1 is of an electromagnet type including an electromagnetic coil 61, a magnetic path 60, and the coil control unit 62, and the axial magnetic flux density of the ion gun 1 can be adjusted by a coil current. The coil control unit 62 includes all components for adjusting a current applied to the electromagnetic coil 61, and providing the ion gun 1 with an appropriate axial magnetic flux density. The control on the axial magnetic flux density is enabled by newly adding a current value of the electromagnetic coil 61 as a control parameter for adjusting the ion beam characteristics, whereby it is possible to dramatically improve the processing speed controllability and the processing profile reproducibility of the ion milling device.

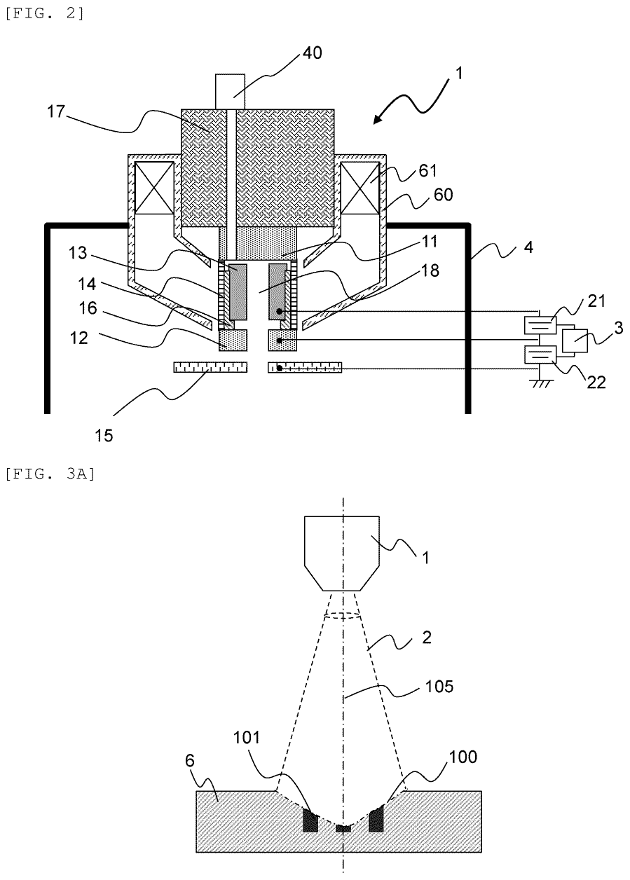

FIG. 2 is a cross-sectional view showing configurations of the ion gun 1 and related peripheral portions. A first cathode 11 is formed of a certain conductive magnetic material such as pure iron and in a disk shape, and is provided with a hole for introducing the gas into an ionization chamber 18. A second cathode 12 is formed of a certain conductive magnetic material such as pure iron and in a disk shape, and is provided with a cathode outlet hole in a central portion. The first cathode 11 and the second cathode 12 are connected to a cathode ring 14 and face each other. An insulator 16 formed in a cylindrical shape is disposed inside the cathode ring 14. An anode 13 is fitted into the insulator 16, an outer surface of the anode 13 is in contact with an inner surface of the insulator 16, and the inner surface faces the ionization chamber 18. The anode 13 is formed of a non-magnetic material having conductivity such as aluminum. The anode 13 is electrically insulated from the first cathode 11, the second cathode 12, and the cathode ring 14 by the insulator 16. An acceleration electrode 15 is a non-magnetic material having conductivity such as stainless steel, and is provided with an acceleration electrode outlet hole in a central portion.

The magnetic field generation device of the ion gun 1 is of an electromagnet type including the electromagnetic coil 61, the magnetic path 60, and the coil control unit 62. The electromagnetic coil 61 is provided on an outer peripheral portion of an ion gun base 17 outside the vacuum chamber 4, and the magnetic path 60 formed to surround the electromagnetic coil 61 is provided with an opening to surround the cathode ring 14 of the ion gun 1 installed in the vacuum chamber 4. When a current flows through the electromagnetic coil 61, the electromagnetic coil 61 generates heat. The electromagnetic coil 61 is disposed outside the vacuum chamber 4, whereby heat dissipation of the electromagnetic coil 61 can be facilitated.

The gas supply mechanism 40 is connected to the ion gun base 17, and includes all components for adjusting the flow rate of the gas to be ionized, and supplying the gas to be ionized into the ion gun. Here, a case of the Ar gas will be described as an example.

The ion gun base 17 and the cathode 11 are provided with holes, and the Ar gas introduced from the gas supply mechanism 40 is introduced into the ionization chamber 18. The Ar gas introduced into the ionization chamber 18 is brought into a state where an appropriate gas partial pressure is maintained, and a discharge voltage of about 0 kV to 4 kV is applied between the first cathode 11 as well as the second cathode 12 and the anode 13 by a discharge power supply 21, thereby generating electrons by a potential difference between the anode and the cathodes. In the ionization chamber 18, trajectories of the generated electrons are bent by a magnetic field generated by the electromagnetic coil 61 and the magnetic path 60 to perform a swirling motion, and further perform a reciprocating motion between the first cathode 11 and the second cathode 12 having the same potential. When the electrons that swirl in the ionization chamber 18 collide with the Ar gas, the Ar gas that receives the collision is ionized, and cations are generated in the ionization chamber 18. Further, an acceleration voltage of about 0 kV to 10 kV is applied between the cathode 12 and the acceleration electrode 15 by an acceleration power supply 22, whereby the Ar ions are accelerated, and the ion beam 2 is emitted to the outside of the ion gun 1. In this way, a part of the cations generated in the ionization chamber 18 passes through the cathode outlet hole of the second cathode 12, are accelerated by the acceleration electrode 15, is emitted from the acceleration electrode outlet hole to the outside of the ion gun 1, and the sample 6 is processed by the ion beam 2 formed of the cations.

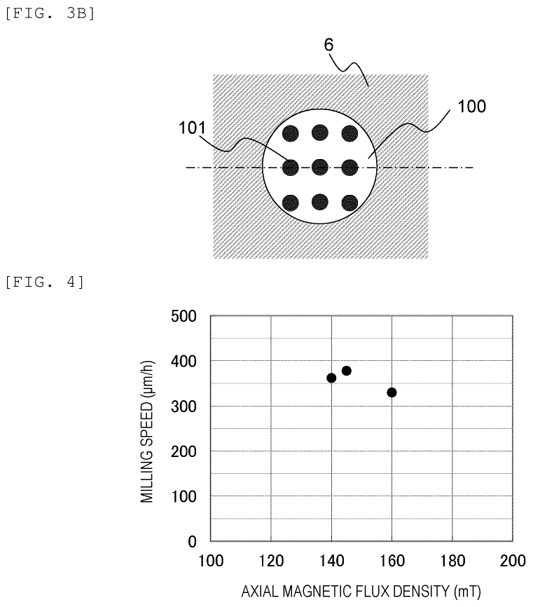

FIGS. 3A and 3B show schematic views of the ion beam 2 emitted from the ion gun 1 and the sample 6 processed by the ion beam 2. FIG. 3A is a cross-sectional view of the ion gun 1, the ion beam 2, and the sample 6. FIG. 3B is a top view of the sample 6. As shown in FIG. 3A, since the ion beam 2 emitted from the ion gun 1 is emitted to the sample 6 without being focused, a Gaussian distribution shape is formed around a beam center 105. Therefore, the ion beam distribution at the ion beam irradiation point of the sample 6 has characteristics that the ion density is the highest at a central portion and the ion density decreases from the center toward the outside. The ion density is directly linked to the processing speed of the sample, and a milling region 100 on a surface of the sample 6 has a shape in which a processing amount is the largest at the central portion of the ion beam irradiation and the processing amount decreases from the center toward the outside. When a measurement pattern 101 appearing in the milling region 100 is observed with an electron microscope and a shape evaluation thereof is used as a management value of a mass production process, a shape of the measurement pattern 101 appearing in the milling region 100 changes depending on a processing depth and an inclination angle of the milling region 100. In order to obtain a correct evaluation result, high accuracy is required for reproducibility of the processing shape.

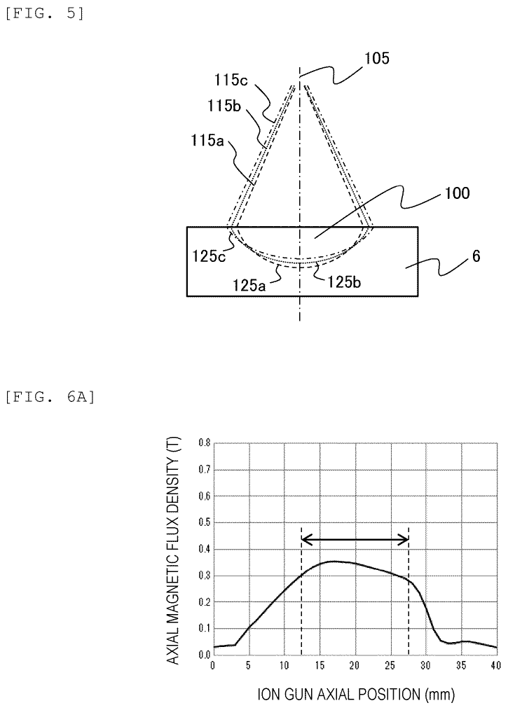

FIG. 4 is a diagram showing a relationship between the milling speed and the axial magnetic flux density of the ion gun. In an experiment, an ion gun using a permanent magnet as the magnetic field generation device was used, and applied milling conditions were as follows: the acceleration voltage conditions were 6 kV, the discharge voltage was 1.5 kV, the Ar gas was used as a gas introduced into the ion gun, and the flow rate of the Ar gas was 0.07 cm³/min. The material to be processed was silicon, a surface of the sample 6 was perpendicularly irradiated with the ion beam 2 as shown in FIG. 3A, and a milling time was set to one hour. As can be seen from FIG. 4, in a case of the axial magnetic flux density of 140 mT, the milling speed is 360 μm/hr, and the milling speed increases to 385 μm/hr at an axial magnetic flux density of 145 mT, and decreases to 340 μm/hr at an axial magnetic flux density of 160 mT. In this way, the axial magnetic flux density of the ion gun 1 is a factor that greatly influences the milling speed, that is, the ion beam intensity. When the magnetic field generation device is the permanent magnet, such an individual difference is the machine difference, and the reproducibility decreases. Further, due to an increase in a temperature of the ion gun 1 during the emission of the ion beam, performance of the permanent magnet deteriorates due to heating. In this way, when the magnetic field generation device of the ion gun 1 is the permanent magnet, a variation in the axial magnetic flux density due to the individual difference and temporal deterioration is large, and a variation in the ion beam characteristics due to the axial magnetic flux density may not be corrected by another control parameter depending on a magnitude of a difference in the axial magnetic flux density.

FIG. 5 schematically shows a state where the processing depth and the processing shape vary due to the influence of the axial magnetic flux density in the penning discharge ion gun 1. The axial magnetic flux density influences the swirling motion of the electrons generated in the ionization chamber 18. That is, since a diameter of the electron swirling is changed by the axial magnetic flux density, spreading of a plasma region and a plasma density are influenced, and the ion beam characteristics vary. As shown in FIG. 5, the influence affects spreading of an ion beam 115, and a processing profile 125 also varies. As described with reference to FIGS. 3A and 3B, when the processing profile 125 of the milling region 100 cannot be formed with high reproducibility, the shape of the appearing measurement pattern 101 changes, and the measurement pattern 101 cannot be applied to mass production process management.

In order to implement the high processing speed controllability and the high processing profile reproducibility in the ion milling device as described above, it is clear that adjustment of the discharge voltage and the gas flow rate in a related-art manner is insufficient, and adjustment of the axial magnetic flux density is essential.

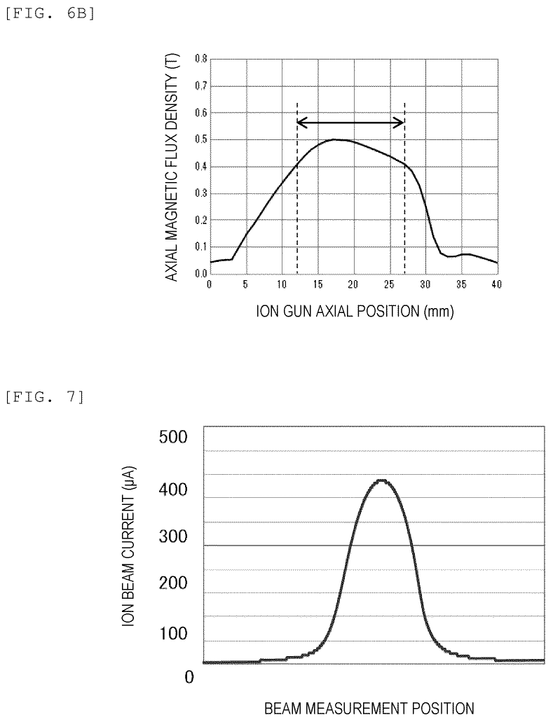

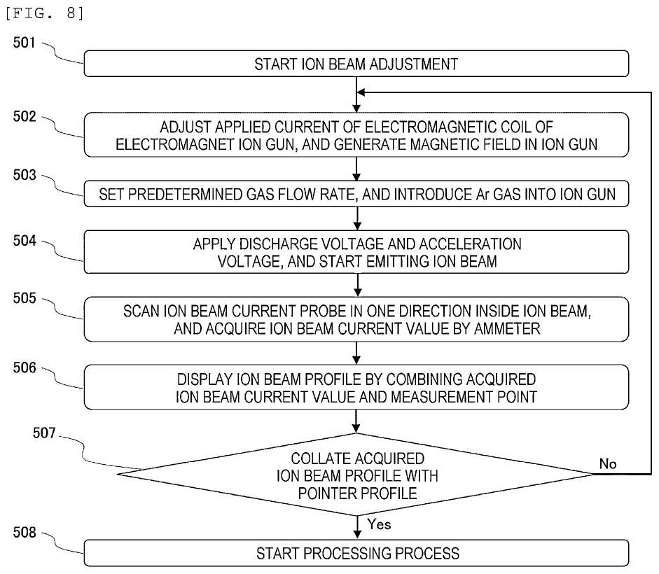

The magnetic field generation device of the ion gun 1 is of the electromagnet type including the electromagnetic coil 61, the magnetic path 60, and the coil control unit 62, whereby the axial magnetic flux density of the ion gun 1 can be adjusted by the coil current. FIGS. 6A and 6B show simulation results of a profile of the axial magnetic flux density for the electromagnet ion gun 1. FIG. 6A shows the profile of the axial magnetic flux density when the value of the current applied to the electromagnetic coil 61 is 2.6 A, and a maximum magnetic field is 350 mT. FIG. 6B shows the profile of the axial magnetic flux density when the value of the current applied to the electromagnetic coil 61 is 3.7 A, and a maximum magnetic field is 500 mT. A range indicated by arrows in each of the magnetic field profiles corresponds to the ionization chamber 18. When FIG. 6A is compared with FIG. 6B, it can be seen that the magnetic field profiles of the ionization chamber 18 have similar shape, and by increasing the current value, a shape of the magnetic field profile is lifted in a high density direction without being changed. Thus, it can be seen that the profile control of the ion beam based on the adjustment of the axial magnetic flux density is effective.

In the ion milling device 300, in order to control the ion beam characteristics by adjusting the axial magnetic flux density of the ion gun, the ion beam characteristic measurement mechanism is provided. FIG. 7 shows an ion beam profile measured by the current probe 52. A horizontal axis indicates a beam measurement position, and a vertical axis indicates an ion beam current measured by the current probe 52.

Since the ion beam profile to be measured is measured as a sum of the ion beam profile formed by the Ar ions flowing due to colliding with the current probe 52 and a background noise profile formed by electrons generated due to irradiation with the ion beam, it is necessary to remove an influence of the background noise profile from the ion beam profile to be measured. The background noise profile varies depending on a measurement position due to a variation in generating secondary electrons or backscattered electrons, and a difference in a collision amount of the electrons with the current probe 52 due to a beam measurement position. Since the secondary electrons and the backscattered electrons generated by collision with the Ar ions have negative charges, an electron trap 55 is disposed near the trajectory of the current probe 52, and the apparatus control unit 200 applies a positive voltage from a power supply 53 to the electron trap 55. In this way, the generated secondary electrons and the generated backscattered electrons are captured and removed by the electron trap 55, whereby it is possible to improve accuracy of the ion beam profile. An electron trap drive unit 54 that moves the electron trap 55 is provided such that the electron trap 55 does not block the ion beam 2 when processing the sample 6. Further, in order to prevent the ions from colliding with the electron trap 55 and becoming a noise generation source, it is desirable that a light element and a material having low sputtering yield is used as the electron trap 55. Specifically, it is desirable to use graphite carbon.

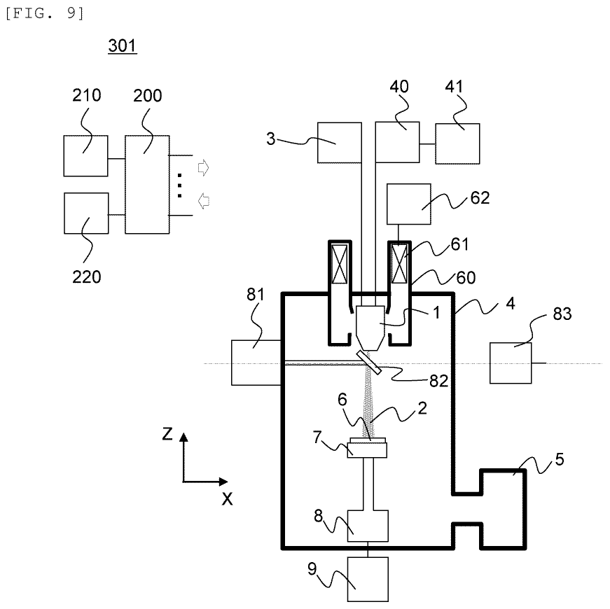

A method for acquiring the ion beam characteristics and adjusting the axial magnetic flux density of the ion gun 1 in the ion milling device 300 shown in FIG. 1 will be described using a flowchart in FIG. 8.

501: After the sample 6 is loaded on the sample stand 7, the apparatus control unit 200 vacuum-exhausts the vacuum chamber 4 by the vacuum exhaust system 5. A target ion beam profile (referred to as a pointer profile) is read and displayed on the display unit 210.

502: The apparatus control unit 200 controls the coil control unit 62, applies coil current conditions held as initial settings to the electromagnetic coil 61 of the electromagnet ion gun 1, and generates a magnetic field having a desired axial magnetic flux density in the ion gun 1.

503: The apparatus control unit 200 supplies the ion gun 1 with the Ar gas whose flow rate is controlled by the gas supply mechanism 40.

504: The apparatus control unit 200 sets the ion beam irradiation conditions held as processing conditions by the ion gun control unit 3, and emits the ion beam 2 from the ion gun 1. The ion beam irradiation conditions determined as the processing conditions are the acceleration voltage and the discharge voltage of the ion gun 1.

505: After starting the ion beam emission, the apparatus control unit 200 controls the current probe drive unit 51 to measure the ion beam current value by the ammeter 50 while reciprocally moving the current probe 52 in the X direction.

506: The apparatus control unit 200 acquires the ion beam profile by associating a position of the current probe 52 in the X direction with an ion beam current value measured by the ammeter 50 at the position. The apparatus control unit 200 displays the acquired ion beam profile together with the pointer profile on the display unit 210.

507: The apparatus control unit 200 collates the ion beam profile acquired in step 506 with the pointer profile read in step 501, and starts the processing process when a desired ion beam profile can be acquired, and repeats steps from the adjustment of the applied current of the electromagnetic coil (step 502), and adjusts the axial magnetic flux density conditions to acquire the ion beam profile again when the desired ion beam profile cannot be acquired. When a difference between the acquired ion beam profile and the pointer profile is small, the discharge voltage may be controlled by the ion gun control unit 3, and the flow rate of the Ar gas may be controlled by the gas supply mechanism 40.

508: The processing process is started.

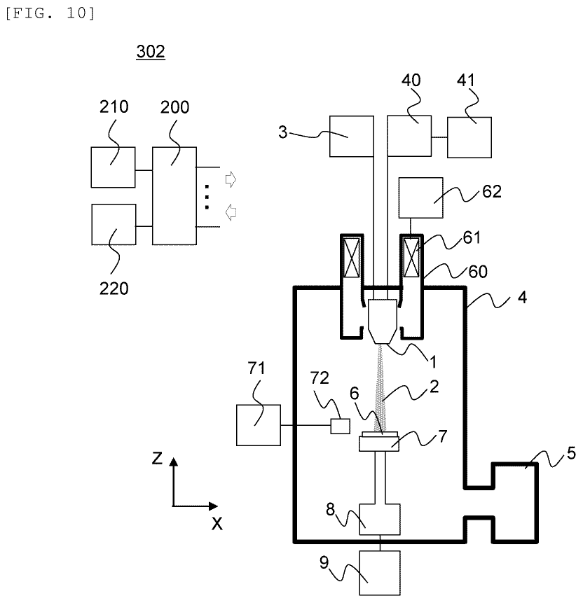

FIG. 9 is a schematic view showing a main part of an ion milling device 301 including an ion beam characteristic measurement mechanism different from that of the example in FIG. 1. Components the same as those of FIG. 1 are denoted by the same reference numerals, and repeated description thereof will be omitted.

The ion beam characteristic measurement mechanism of the ion milling device 301 includes a phosphor 82 formed on a thin-film body; a phosphor drive unit 81 that drives the phosphor such that the phosphor 82 is irradiated with the ion beam; and a camera 83 that is provided at a position that is not irradiated with the ion beam 2 and images the phosphor 82, and the ion beam characteristic measurement mechanism measures an intensity distribution of the ion beam 2 based on imaging data, which utilizes a fact that an emission intensity of the phosphor 82 depends on an intensity of the ion beam. A two-dimensional intensity distribution of the ion beam 2 along a phosphor screen may be treated as the ion beam profile, or an intensity distribution of the ion beam 2 along an optional one-dimensional direction may be treated as the ion beam profile. When an intensity distribution of the ion beam 2 along the X direction is extracted, data corresponding to the ion beam profile measured by the ion beam characteristic measurement mechanism in FIG. 1 is obtained. Accordingly, the beam intensity distribution of the ion beam 2 emitted by the ion gun 1 can be estimated, and the axial magnetic flux density can be adjusted according to the flowchart in FIG. 8.

FIG. 10 is a schematic view showing a main part of an ion milling device 302 including an ion beam characteristic measurement mechanism different from that of the example in FIG. 1. Components the same as those of FIG. 1 are denoted by the same reference numerals, and repeated description thereof will be omitted. In the examples in FIGS. 1 and 9, each of the ion beam characteristic measurement mechanisms uses the ion beam profile indicating the intensity distribution of the ion beam current of the ion beam as the ion beam characteristics for estimating the processing profile of the sample 6 processed by the ion beam 2. Meanwhile, in the example in FIG. 10, the ion beam characteristic measurement mechanism estimates a milling amount per unit time of the sample 6 processed by the ion beam 2, and uses the milling amount as the ion beam characteristics.

The ion beam characteristic measurement mechanism of the ion milling device 302 includes a probe 72 disposed near the sample stand 7 on which the sample 6 is placed. The probe 72 is a quartz crystal resonator, and is oscillated at a constant frequency when a voltage is applied. An object flicked from the sample 6 by collision of the ions emitted from the ion gun 1 is re-adhered to the probe 72, whereby mass of the probe 72 changes. Accordingly, since the oscillation frequency of the quartz crystal resonator changes, a change in an adhesion amount of the object based on a change in the oscillation frequency is calculated by a film thickness meter 71, whereby it is possible to estimate the milling amount per unit time of the sample processed by the ion beam.

When the processing profiles of the sample 6 are the same, amounts of the object generated by processing the sample 6 and adhered to the probe 72 are also the same. Therefore, in the ion milling device 302, since the beam intensity of the ion beam 2 during processing can be estimated, the apparatus control unit 200 may control the axial magnetic flux density of the ion gun 1 such that the change in the adhesion amount of the object during processing of the sample 6, or the change in the oscillation frequency of the quartz crystal resonator 72 is in a predetermined range.

### REFERENCE SIGNS LIST

1: ion gun
2: ion beam
3: ion gun control unit
4: vacuum chamber
5: vacuum exhaust system
6: sample
7: sample stand
8: sample stage
9: sample stage drive unit
11: first cathode
12: second cathode
13: anode
14: cathode ring
15: acceleration electrode
16: insulator
17: ion gun base
18: ionization chamber
21: discharge power supply
22: acceleration power supply
40: gas supply mechanism
41: gas source
50: ammeter
51: current probe drive unit
52: current probe
53: power supply
54: electron trap drive unit
55: electron trap
60: magnetic path
61: electromagnetic coil
62: coil control unit
71: film thickness meter
72: probe
81: phosphor drive unit
82: phosphor
83: camera
100: milling region
101: measurement pattern
105: ion beam center
115a, 115b, 115c: ion beam
125a, 125b, 125c: processing profile
200: apparatus control unit
210: display unit
220: input unit
300, 301, 302: ion milling device

1. An ion milling device comprising:
a vacuum chamber whose internal pressure is controlled by a vacuum exhaust system;
an ion gun attached to the vacuum chamber and configured to emit an unfocused ion beam;
a sample stand disposed in the vacuum chamber and configured to hold a sample;
an ion beam characteristic measurement mechanism configured to measure an ion beam characteristic for estimating a processing profile of the sample processed by the ion beam; and
a control unit, wherein
a magnetic field generation device configured to generate a magnetic field in an ionization chamber of the ion gun is an electromagnet including an electromagnetic coil and a magnetic path, and
the control unit controls a value of a current, which is applied to the electromagnetic coil, based on the ion beam characteristic measured by the ion beam characteristic measurement mechanism.

2. The ion milling device according to claim 1, wherein
the ion beam characteristic measurement mechanism measures an ion beam profile indicating an intensity distribution of an ion beam current of the ion beam as the ion beam characteristic.

3. The ion milling device according to claim 2, wherein
the ion beam characteristic measurement mechanism includes a linear ion beam current probe that extends in a first direction, and a current probe drive unit configured to move the ion beam current probe along a trajectory that extends in a second direction orthogonal to the first direction to cross the ion beam, and
the control unit measures the ion beam profile by associating an ion beam current that flows through the ion beam current probe with a position on the trajectory of the ion beam current probe.

4. The ion milling device according to claim 3, wherein
the ion beam characteristic measurement mechanism includes an electron trap disposed near the trajectory, and
the control unit applies a predetermined positive voltage to the electron trap during a period in which the ion beam characteristic measurement mechanism measures the ion beam profile.

5. The ion milling device according to claim 2, wherein
the ion beam characteristic measurement mechanism includes a phosphor formed on a thin-film body, a phosphor drive unit configured to drive the phosphor such that the phosphor is irradiated with the ion beam, and a camera configured to image the phosphor, and
the control unit measures the ion beam profile based on imaging data of the camera.

6. The ion milling device according to claim 2, wherein
the control unit reads a pointer profile targeted by the ion beam, and adjusts the value of the current applied to the electromagnetic coil such that the ion beam profile measured by the ion beam characteristic measurement mechanism matches the pointer profile.

7. The ion milling device according to claim 1, wherein
the ion beam characteristic measurement mechanism estimates a milling amount per unit time of the sample processed by the ion beam as the ion beam characteristic.

8. The ion milling device according to claim 7, wherein
the ion beam characteristic measurement mechanism includes a quartz crystal resonator held near the sample stand, and
the control unit measures the ion beam characteristic based on an oscillation frequency of the quartz crystal resonator that changes in response to a fact that an object flicked from the sample when the sample is irradiated with the ion beam is adhered to the quartz crystal resonator.

9. The ion milling device according to claim 1, wherein
the ion gun includes
a gas supply source configured to supply a gas to the ionization chamber,
a first cathode and a second cathode facing each other,
a cathode ring disposed between the first cathode and the second cathode, and
an anode disposed in a state of being electrically insulated from the cathode ring and configured to be applied with a positive voltage with respect to potentials of the first cathode and the second cathode,
the ionization chamber is a region surrounded by the first cathode, the second cathode, and the anode, and
the magnetic path of the magnetic field generation device is provided with an opening to surround the cathode ring.

10. The ion milling device according to claim 9, wherein
the electromagnetic coil of the magnetic field generation device is provided outside the vacuum chamber.
